(19) United States
(12) Patent Application Publication
(10) Pub. No.: US 2014/0367674 A1
(43) Pub. Date: Dec. 18, 2014

(54) PROCESS FOR FORMING AN AMORPHOUS CONDUCTIVE OXIDE FILM

(71) Applicant: JAPAN SCIENCE AND TECHNOLOGY AGENCY, Kawaguchi-shi (JP)

(72) Inventors: Tatsuya Shimoda, Nomi-shi (JP); Jinwang Li, Kanazawa-shi (JP)

(73) Assignee: JAPAN SCIENCE AND TECHNOLOGY AGENCY, Kawaguchi-shi (JP)

(21) Appl. No.: 14/344,072

(22) PCT Filed: Nov. 15, 2012
(86) PCT No.: PCT/JP2012/080254

§ 371 Date: Mar. 11, 2014

(30) Foreign Application Priority Data
Nov. 18, 2011 (JP) 2011-252387

(51) Int. Cl. H01L 21/02; H01L 29/24

(52) U.S. Cl. CPC H01L 21/02565; H01L 21/02614; H01L 29/247
USPC 257/43; 438/104; 252/519.3

(57) ABSTRACT

A process for forming an amorphous conductive oxide film, comprising the steps of: applying a composition which comprises (A1) a×y parts by mole of at least one metal compound selected from the group consisting of carboxylate salts, alkoxides, diketonates, nitrate salts and halides of a metal selected from among lanthanoids (excluding cerium), (A2) a×(1−y) parts by mole of at least one metal compound selected from the group consisting of carboxylate salts, alkoxides, diketonates, nitrate salts and halides of a metal selected from among lead, bismuth, nickel, palladium, copper and silver, (B) 1 part by mole of at least one metal compound selected from the group consisting of carboxylate salts, alkoxides, diketonates, nitrate salts, halides, nitrosylcarboxylate salts, nitrosylnitrate salts, nitrosylsulfate salts and nitrosylhalides of a metal selected from among ruthenium, iridium, rhodium and cobalt, and (C) a solvent containing at least one selected from the group consisting of carboxylic acids, alcohols, ketones, diols and glycol ethers to a substrate to form a coating film; and heating the coating film in an oxidizing atmosphere.

### TECHNICAL FIELD

The present invention relates to a process for forming an amorphous conductive oxide film. More specifically, it relates to a process for easily forming an amorphous conductive oxide film which exhibits high electrical conductivity and a novel amorphous conductive oxide film which exhibits p-type semiconducting properties.

### BACKGROUND ART

Semiconductor devices such as diodes and transistors exhibit their functions due to junction between semiconductors which show different types of electrical conductivity. As examples of the above junction, there are known pn-junction and pin-junction. These semiconductors have been produced by using metalloid elements such as silicon and germanium for a long time. The metalloid element materials are not always satisfactory as semiconductor materials used industrially because their production costs are high and they tend to deteriorate at a high temperature.

In this respect, oxide semiconductors such as In—Ga—Zn—O-based semiconductors are expected as materials having attractive properties because films can be formed by a simple method such as a coating method at a low temperature, the ambient atmosphere at the time of film formation does not need to be controlled particularly, and further the obtained thin films are optically transparent.

However, since most of known oxide semiconductors are n-type semiconductors, a conventional material must be used in at least part of a semiconductor device for practical use. Therefore, the above problem has not been completely solved yet.

There are only a few reports about oxide semiconductors which exhibit p-type electrical conductivity. For example, non-patent document 1 (Applied Physics Letters 97, 072111 (2010)) and non-patent document 2 (Applied Physics Letters 93, 032113 (2008)) disclose crystalline SnO which exhibits p-type electrical conductivity. However, the process for producing crystalline SnO is complicated. According to the above non-patent document 1, for example, an amorphous SnO film is deposited on a substrate by radio frequency magnetron sputtering, a SiO₂ cap layer is then formed on the above amorphous SnO film by sputtering, and two-stage annealing is carried out by changing the ambient atmosphere and the temperature to obtain a crystalline SnO thin film which exhibits p-type electrical conductivity. It cannot be said that this complicated production process is industrially practical, and the crystalline SnO film formed by this process is unsatisfactory in terms of p-type semiconducting properties.

Meanwhile, conductive oxides are widely used as conductive materials constituting electrodes and wires in various electronic devices. When a crystalline oxide is used as a conductive oxide, it is pointed out that there is limitation to the miniaturization of a device. That is, it is known that, when the size of an electrode or wire constituted from a crystalline material becomes close to the crystal size, electrical conductivity does not become continuous. Therefore, the size of an electrode must be at least 3 times the crystal size. When an amorphous conductive oxide is used, since there is no such limitation, it is possible to form a very small electrode.

As the amorphous conductive oxide, there are known, for example, IZO (indium-zinc composite oxide) and IGZO (indium-gallium-zinc composite oxide). Films made from these amorphous conductive oxides have been formed, for example, by a vapor-phase process such as sputtering, laser ablation or vapor deposition. However, since the vapor-phase process requires a bulky and expensive apparatus and has low film productivity, the cost required for film formation imposes a great burden.

In recent years, a technology for forming an amorphous conductive oxide film by a more inexpensive liquid-phase process has been reported. For example, the technology disclosed by non-patent document 3 (C. K. Chen, et al., Journal of Display Technology, Vol. 5, No. 12, pp 509-514 (2009)) is for forming an IZO film by applying a composition solution containing indium chloride and zinc chloride as an oxide precursor to a substrate and heating the coating film. However, the film obtained by this technology is unsatisfactory in terms of electrical conductivity and not put to practical use yet. Further, amorphous IZO and IGZO have low heat stability and therefore, cannot be used in electronic devices which require a high processing temperature.

Under the above circumstances, a process for forming an amorphous conductive oxide film having high stability and high electrical conductivity by an inexpensive liquid-phase process is desired.

### DISCLOSURE OF THE INVENTION

It is an object of the present invention which has been made in view of the above circumstances to provide a simple process for producing a novel amorphous conductive oxide film which can be used in the semiconductor device industry, specifically an amorphous conductive oxide film which exhibits p-type semiconducting properties.

The above object and advantage of the present invention are attained by a process for forming an amorphous conductive oxide film, comprising the steps of:

applying a composition which comprises (A1)) a×y parts by mole of at least one metal compound selected from the group consisting of carboxylate salts, alkoxides, diketonates, nitrate salts and halides of a metal selected from among lanthanoids (excluding cerium), (A2) a×(1−y) parts by mole of at least one metal compound selected from carboxylate salts, alkoxides, diketonates, nitrate salts and halides of a metal selected from among lead, bismuth, nickel, palladium, copper and silver, (B) 1 part by mole of at least one metal compound selected from the group consisting of carboxylate salts, alkoxides, diketonates, nitrate salts, halides, nitrosylcarboxylate salts, nitrosylnitrate salts, nitrosylsulfate salts and nitrosylhalides of a metal selected from among ruthenium, iridium, rhodium and cobalt (at least one of the above metal compounds is selected from among carboxylate salts, alkoxides, diketonates and nitrosylcarboxylate salts of a metal, “a” is a number of 0.3 to 6.0, “y” is a number of 0 or more and less than 1), and (C) a solvent containing at least one selected from the group consisting of carboxylic acids, alcohols, ketones, diols and glycol ethers to a substrate to form a coating film; and heating the coating film in an oxidizing atmosphere.

### BRIEF DESCRIPTION OF THE DRAWINGS

FIG. 1 is an X-ray diffraction chart of an oxide film having a metal atom ratio Pb_{1.0}Ru_{1.0} formed in Example 1;

FIG. 2 is an X-ray diffraction chart of an oxide film having a metal atom ratio Bi_{1.0}Ru_{1.0} formed in Example 1;

FIG. 3 is an X-ray diffraction chart of an oxide film having a metal atom ratio Bi_{1.0}Ir_{1.0} formed in Example 1;

FIG. 4 is an X-ray diffraction chart of an oxide film having a metal atom ratio Bi_{1.0}Rh_{1.0} formed in Example 1;

FIG. 5 is an X-ray diffraction chart of an oxide film having a metal atom ratio Ni_{1.0}Rh_{1.0} formed in Example 1;

FIG. 6 is an X-ray diffraction chart of an oxide film having a metal atom ratio Ni_{1.0}Rh_{1.0}Ir_{1.0} formed in Example 1;

FIG. 7 is an X-ray diffraction chart of an oxide film having a metal atom ratio Ni_{2.0}Rh_{1.0}Ir_{1.0} formed in Example 1;

FIG. 8 is an X-ray diffraction chart of an oxide film having a metal atom ratio La_{0.5}Rb_{0.5}Ru_{1.0} formed in Example 1;

FIG. 9 is an X-ray diffraction chart of an oxide film having a metal atom ratio La_{0.3}Bi_{0.7}Ru_{1.0} formed in Example 1;

FIG. 10 is an X-ray diffraction chart of an oxide film having a metal atom ratio La_{0.3}Bi_{0.7}Ir_{1.0} formed in Example 1;

FIG. 11 is an X-ray diffraction chart of LaPbRu-based oxide films formed in Example 1;

FIG. 12 is an X-ray diffraction chart of LaBiRu-based oxide films formed in Example 1;

FIG. 13 is a graph showing the temperature dependence of the Seebeck coefficients of oxide films formed in Example 2;

FIG. 14 is a graph showing the temperature dependence of the Seebeck coefficients of oxide films formed in Example 2;

FIG. 15 is a schematic sectional view showing the structure of a thin-film transistor produced in Example 5;

FIG. 16 shows the current transfer characteristics of the thin-film transistor produced in Example 5; and

FIG. 17 shows the output characteristics of the thin-film transistor produced in Example 5.

### BEST MODE FOR CARRYING OUT THE INVENTION

The present invention will be described in detail hereinunder.

As described above, the process for forming an amorphous conductive oxide film according to the present invention comprises the steps of:

applying a composition (may also be referred to as “precursor composition” hereinafter) which comprises (A1) at least one metal compound (to be referred to as “metal compound (A1)” hereinafter) selected from the group consisting of carboxylate salts, alkoxides, diketonates, nitrate salts and halides of a metal selected from among lanthanoids (excluding cerium), (A2) at least one metal compound (to be referred to as “metal compound (A2)” hereinafter) selected from the group consisting of carboxylate salts, alkoxides, diketonates, nitrate salts and halides of a metal selected from among lead, bismuth, nickel, palladium, copper and silver, (B) at least one metal compound (to be referred to as “metal compound (B)” hereinafter) selected from the group consisting of carboxylate salts, alkoxides, diketonates, nitrate salts, halides, nitrosylcarboxylate salts, nitrosylnitrate salts, nitrosylsulfate salts and nitrosylhalides of a metal selected from among ruthenium, iridium, rhodium and cobalt, and (C) at least one solvent (to be referred to as “solvent (C)” hereinafter) selected from the group consisting of carboxylic acids, alcohols, ketones, diols and glycol ethers to a substrate to form a coating film; and

heating the coating film in an oxidizing atmosphere.

In this text, the lanthanoids excluding cerium (elements having atomic numbers 57 and 59 to 71) may be simply referred to as “lanthanoids” collectively. In this text, when the lanthanoids are represented by a chemical formula in this sense, the symbol “Ln” is used.

Any one of the elements having atomic numbers 57 and 59 to 71 may be advantageously used as the above lanthanoid. Cerium is excluded. As the lanthanoid, at least one selected from the group consisting of lanthanum, praseodymium, neodymium, samarium, europium and gadolinium is preferably used, and lanthanum is more preferably used.

The above carboxylate salts of lanthanoids, lead, bismuth, nickel, palladium, copper, silver, ruthenium, iridium, rhodium and cobalt are preferably carboxylate salts having an alkyl group with 1 to 10 carbon atoms, more preferably carboxylate salts having an alkyl group with 1 to 8 carbon atoms, as exemplified by acetate salts, propionate salts, butyrate salts, valerate salts and 2-ethylhexanoate salts of these metals. Out of these, acetate salts, propionate salts and 2-ethylhexanoate salts are preferred from the viewpoints of the acquisition ease and synthesis ease of these salts. These carboxylate salts may be anhydrous or hydrous salts.

The number of carbon atoms of the alkoxy group in the above alkoxides of lanthanoids, lead, bismuth, nickel, palladium, copper, silver, ruthenium, iridium, rhodium and cobalt is preferably 1 to 6, more preferably 1 to 4. For example, the alkoxides may be methoxides, ethoxides, propoxides or butoxides of these metals. These alkoxides may be anhydrous or hydrous salts.

Examples of the diketone ligand in the above diketonates of lanthanoids, lead, bismuth, nickel, palladium, copper, silver, ruthenium, iridium, rhodium and cobalt include acetylacetone and 2,2,6,6-tetramethyl-3,5-heptanedionato. These diketonates may be anhydrous or hydrous salts.

The above nitrate salts of lanthanoids, lead, bismuth, nickel, palladium, copper, silver, ruthenium, iridium, rhodium and cobalt and the above halides of these metals may be anhydrous or hydrous salts. The halogen atom in the above halides is preferably a chlorine atom, bromine atom or iodine atom.

The above nitrosylcarboxylate salts of ruthenium, iridium, rhodium and cobalt are compounds which are generally represented by a chemical formula M(NO)(OOCR)ₙ (M is ruthenium, iridium, rhodium or cobalt; R is an alkyl group; when M is ruthenium or iridium, “n” is 3; when M is rhodium or cobalt, “n” is 2). R is preferably an alkyl group having 1 to 10 carbon atoms, more preferably an alkyl group having 1 to 8 carbon atoms. This nitrosylcarboxylate salt is preferably a nitrosylacetate salt, nitrosylpropionate salt, nitrosylbutyrate salt, nitrosylvalerate salt or nitrosyl-2-ethylhexanoate salt, more preferably a nitrosylacetate salt. These nitrosylcarboxylate salts may be anhydrous or hydrous salts.

The above nitrosylnitrate salts and nitrosylsulfate salts of ruthenium, iridium, rhodium and cobalt are salts which are generally represented by chemical formulas M(NO) (NO₃)ₙ and Mⱼ(NO)ₖ(SO₄)ₘ (M is ruthenium, iridium, rhodium or cobalt; when M is ruthenium or iridium, “n” is 3, “j” is 2, “k” is 2 and “m” is 3; when M is rhodium or cobalt, “n” is 2, “j” is 1, “k” is 1 and “m” is 1), respectively. They may be anhydrous or hydrous salts.

The above nitrosylhalides of ruthenium, iridium, rhodium and cobalt are salts which are generally represented by a chemical formula MNOXᵢ (M is ruthenium, iridium, rhodium or cobalt, X is a halogen atom, when M is ruthenium or iridium, “i” is 3, and when M is rhodium or cobalt, “i” is 2). They may be anhydrous or hydrous salts.

At least one out of the metal compounds used in the present invention is selected from carboxylate salts, alkoxides, diketonates and nitrosylcarboxylate salts of a metal. This requirement ensures that a significant amount of a carbon atom, a hydrogen atom or both is involved in at least the process of forming an oxide film. Due to this requirement, the oxide film formed by the process of the present invention exhibits novel characteristic properties which are not obtained in the prior art.

The ratio of these metal compounds is as follows.

Metal compound (A1): a×y parts by mole
Metal compound (A2): a×(1−y) parts by mole
Metal compound (B): 1 part by mole

Here, “a” is a number of 0.3 to 6.0, and “y” is a number of 0 or more and less than 1. Here, “a” is preferably a number of 0.3 to 2.0, more preferably 0.5 to 1.5.

“y” is preferably a number of 0 to 0.8, more preferably 0 to 0.5.

Here, when the precursor composition used in the present invention comprises the metal compound (A1) preferably in the above range, the formed oxide film tends to have an amorphous structure regardless of the type of the metal compound (B). When the precursor composition does not comprise the metal compound (A1) and a rhodium compound is used as the metal compound (B), a stable amorphous structure tends to be easily obtained.

The formed oxide film exhibits high electrical conductivity while it is rarely affected by the types of the metal compounds contained in the precursor composition. Provided that at least one selected from ruthenium and iridium compounds is used as the metal compound (B), an oxide film having high electrical conductivity is easily obtained and can be advantageously used in electrodes. However, when a rhodium compound is used as the metal compound (B) or when the ratio of a ruthenium atom is ⅓ (mole/mole) or less based on the total of all metal atoms if a ruthenium compound is used as the metal compound (B), electrical conductivity tends to be slightly low. However, even in these cases, the obtained oxide films have sufficiently high electrical conductivity as a semiconductor and accordingly, have no problem when they are used as semiconductors.

As will be described hereinafter, the electrical conductivity of the oxide film formed by the process of the present invention can be modified through a second heating step under reduced pressure and a third heating step in an oxidizing atmosphere. Therefore, in the process of the present invention, an oxide film having arbitrary electrical conductivity (volume resistivity) can be easily formed by suitably selecting the types of metal compounds and the process.

Further, the oxide film formed by the process of the present invention exhibits p-type semiconducting properties and its Seebeck coefficient as an index for the p-type semiconducting properties is a positive value at a wide temperature range. When a rhodium compound is used as the metal compound (B), the Seebeck coefficient of the obtained oxide film becomes an especially large positive value so that very clear p-type semiconducting properties are obtained.

The solvent (C) contained in the precursor composition used in the present invention contains at least one selected from the group consisting of carboxylic acids, alcohols, ketones, diols and glycol ethers. The solvent in the present invention may further contain at least one selected from the group consisting of aliphatic hydrocarbons, alicyclic hydrocarbons, aromatic hydrocarbons, esters and ethers (excluding glycol ethers. The same shall apply hereinafter).

The above carboxylic acids are preferably carboxylic acids having an alkyl group with 1 to 10 carbon atoms, more preferably carboxylic acids having an alkyl group with 2 to 8 carbon atoms. The above number of carbon atoms includes the number of carbon atoms of a carboxyl group. Examples of the carboxylic acids include propionic acid, n-butyric acid, isobutyric acid, n-hexanoic acid, n-octanoic acid and 2-ethylhexanoic acid.

The above alcohols are preferably primary alcohols, as exemplified by methanol, ethanol, propanol, isopropanol, 1-butanol, sec-butanol, t-butanol, methoxymethanol, ethoxymethanol, 2-methoxyethanol and 2-ethoxyethanol.

The above ketones are preferably ketones having 3 to 10 carbon atoms, more preferably ketones having 4 to 7 carbon atoms. The above number of carbon atoms includes the number of carbon atoms of a carbonyl group. Examples of the ketones include methyl ethyl ketone, methyl isobutyl ketone and diethyl ketone.

The above diols are preferably alkylene glycols, as exemplified by ethylene glycol, propylene glycol and butanediol.

The above glycol ethers are preferably monoalkyl ethers of an alkylene glycol, as exemplified by methoxyethanol, ethoxyethanol and isopropoxyethanol.

The above aliphatic hydrocarbons include hexane and octane; the above alicyclic hydrocarbons include cyclohexane; the above aromatic hydrocarbons include benzene, toluene and xylene; the above esters include methyl acetate, ethyl acetate, methyl propionate, ethyl propionate, methyl butyrate, ethyl acetate, methyl 2-ethylhexanoate and ethyl 2-ethylhexanoate; and the above ethers include diethyl ether, dibutyl ether, ethylene glycol dimethyl ether, ethylene glycol diethyl ether, ethylene glycol ethyl methyl ether, tetrahydrofuran, tetrahydropyran and dioxane.

The solvent in the present invention contains at least one selected from the group consisting of carboxylic acids, alcohols, ketones, diols and glycol ethers. The content of at least one selected from the group consisting of carboxylic acids, alcohols, ketones, diols and glycol ethers in the solvent in the present invention is preferably 50 wt % or more, more preferably 75 wt % or more, most preferably 100 wt % based on the total amount of the solvent from the viewpoints of solubility and the long-term stability of the composition.

When the precursor composition of the present invention is used in a semiconductor device, the solvent is preferably a nonaqueous solvent containing substantially no water. The expression “containing substantially no water” does not exclude the existence of a trace amount of water as an impurity contained in a hydrophilic solvent and includes a case where the water content of the solvent is reduced as much as possible by general efforts made industrially by a person having ordinary skill in the art. The water content of the solvent is preferably 5 wt % or less, more preferably 3 wt % or less, much more preferably 1 wt % or less.

The precursor composition used in the present invention comprises the metal compound (A2), the metal compound (B) and the solvent (C) described above as essential components and optionally the metal compound (A1). As long as the effect of the present invention is not impeded, the precursor composition may comprise other components. The other components include a chelating agent.

The above chelating agent may be contained in the precursor composition of the present invention in order to improve the solubility of the metal compounds and the surface smoothness of the oxide film to be formed. Although the reason that the surface smoothness of the oxide film is improved by the addition of the chelating agent is unknown, the inventors assume as follows. That is, they assume that the chelating agent is chelatingly coordinated to the metal compounds to stabilize the compounds, thereby delaying the decomposition of the compounds in the heating step for film formation which will be described hereinafter with the result that the core of thermal decomposition becomes fine and uniform, whereby the surface of the oxide film becomes more smooth.

The chelating agent having this function is, for example, a compound having two or more of at least one type of group selected from the group consisting of amino group, carbonyl group and hydroxyl group. Examples of the chelating agent include compounds having two or more amino groups such as ethylenediamine and polylethyleneamine; compounds having two or more carbonyl groups such as acetylacetone; compounds having two or more hydroxyl groups such as ethylene glycol and glycerin; and compounds having an amino group and a hydroxyl group such as monoethanolamine. At least one selected from these may be preferably used.

When the precursor composition of the present invention comprises a chelating agent, the content of the chelating agent in the composition is preferably 3 moles or more, more preferably 5 to 20 moles based on 1 mole of the total of the metal compounds in the composition.

The precursor composition of the present invention can be prepared by mixing the above components excluding the solvent and dissolving them in the solvent. At this point, the solvent and these components may be mixed and dissolved at a time, these components may be added to the solvent sequentially, several solutions obtained by dissolving each component in the solvent are mixed together, or another method may be employed. For the preparation of the precursor composition of the present invention, heating may be carried out as required.

The liquid property of the precursor composition of the present invention is preferably set to an acidic range, that is, its pH is set to more preferably 6.5 or less, particularly preferably 3 to 6. By setting this liquid property, a precursor composition having excellent storage stability can be obtained.

The solids content (the ratio of the total weight of the components excluding the solvent (C) of the composition to the total weight of the composition) of the precursor composition of the present invention is preferably 0.1 to 10 wt %, more preferably 0.5 to 6 wt %.

The composition after preparation may be filtered with a filter having a suitable opening diameter before use.

Since the metal compounds which are components of the precursor composition of the present invention may be hydrous salts as described above, the precursor composition may contain water right after its preparation. Since the solvent contains at least one selected from the group consisting of hydrophilic carboxylic acids, alcohols, ketones, diols and glycol ethers, the composition may absorb moisture during use or storage. However, the precursor composition of the present invention can be stored for a long time without controlling the water content of the composition. Therefore, although the precursor composition of the present invention can provide an oxide film which has p-type semiconducting properties as will be described hereinafter and whose electrical conductivity is preferably adjusted to an arbitrary level by a simple process, its preparation cost and storage cost are greatly cut down, thereby contributing to the curtailment of the production cost of an electric device.

However, when the process of the present invention is applied to a semiconductor device, it is preferred to use a precursor composition containing substantially no water. The expression “containing substantially no water” does not exclude the existence of trace amounts of water as an impurity contained in a hydrophilic raw material and water as crystal water and includes a case where the water content of the composition is reduced as much as possible by general efforts made industrially by a person having ordinary skill in the art. The water content of the composition is preferably 5 wt % or less, more preferably 1 wt % or less, particularly preferably 0.5 wt % or less.

The process for forming an amorphous conductive oxide film according to the present invention comprises the steps of applying the above precursor composition to a substrate to form a coating film and heating the coating film in an oxidizing atmosphere.

Although the substrate to be used in the process of the present invention is not particularly limited, for example, a substrate made of quartz; glass such as borosilicate glass, soda glass or quartz glass; plastic; carbon; silicone resin; silicon; metal such as gold, silver, copper, nickel, titanium, aluminum or tungsten; or glass, plastic or silicon having any one of the above metals, an oxide thereof, mixed oxide (such as ITO) or silicon oxide on the surface may be used.

To apply the precursor composition to the substrate, a suitable coating technique such as spin coating, roll coating, curtain coating, dip coating, spraying or droplet discharge method may be employed. Then, the solvent is removed from the liquid film composed of the precursor composition as required so that a coating film can be formed on the substrate. At this point, if the solvent remains in the coating film in some measure, this does not diminish the effect of the present invention. To remove the solvent after application, the composition should be left to stand at a temperature from room temperature to 200° C. for 1 to 30 minutes.

The coating film formed as described above is then heated in an oxidizing atmosphere.

Heating in an oxidizing atmosphere may be preferably carried out a heating operation in an oxygen-containing gas. Air or oxygen is preferably used as the above oxygen-containing gas. The pressure at the time of heating may be arbitrary, for example, 5×10⁴ to 1×10⁶ Pa.

Since a heating temperature of about 250° C. is required to provide suitable electrical conductivity to the formed film, it is preferred to heat the film at a temperature equal to or higher than 250° C. Even when the heating temperature is set to about 400° C., an amorphous state can be maintained. Therefore, generally speaking, the heating temperature is preferably in the range of 250 to 400° C. Since the heating temperature at which the amorphous state can be maintained can be further raised by suitably selecting the types of the metal compounds, the heating temperature may exceed the upper limit of the above temperature range in that case. For example, when the precursor composition comprises the metal compound (A1) preferably in the above range, an amorphous oxide film can be obtained regardless of the type of the metal compound (B) even by heating up to 650° C. On the other hand, when the precursor composition does not comprise the metal compound (A1), the temperature at which the amorphous state can be maintained differs according to the type of the metal compound (B). When the precursor composition does not comprise the metal compound (A1) and a rhodium compound is used as the metal compound (B), an amorphous oxide film can be obtained even by heating up to 650° C. When the precursor composition does not comprise the metal compound (A1) and the metal compound (B) is a ruthenium, iridium or cobalt compound, to obtain an amorphous oxide film, the heating temperature is preferably set to 400° C. or less. The conductive oxide film which is formed at the above preferred heating temperature by the process of the present invention can be a conductive film having an arbitrary very small size which is not limited by the crystal size.

The heating time is preferably 3 minutes or more, more preferably 10 minutes or more. Since an oxide film having sufficiently high semiconducting properties can be formed by heating at the above temperature for the above time in the present invention, it is impractical to keep heating for a long time. However, since the film is not crystallized by further heating the formed oxide film as long as heating is carried out at the above temperature range, long-time heating is not inhibited. However, the heating time is preferably 2 hours or less from the viewpoint of reasonable cost.

An oxide film may be formed by carrying out the steps of applying the precursor composition, optionally removing the solvent and heating one time (one cycle) or repeating this cycle several times for recoating.

Heating may be carried out in a single stage or several stages without changing the heating temperature or by changing the heating temperature, or by changing the heating temperature continuously. When heating is carried out in several stages by changing the heating temperature, it is preferred to raise the heating temperature gradually in each stage. When heating is carried out by changing the heating temperature continuously, it is preferred to raise the heating temperature gradually.

The thickness of the oxide film formed as described above should be suitably set according to its application purpose but may be 20 to 500 nm.

The conductive oxide film formed as described above may undergo a second heating step under reduced pressure and a third heating step in an oxidizing atmosphere after the above step of heating in an oxidizing atmosphere. By carrying out these additional steps, the electrical conductivity (volume resistivity) of the conductive oxide film can be adjusted to a wide range arbitrarily and easily.

As will be described hereinafter, the oxide film formed by the process of the present invention contains significant amounts of a carbon atom and a hydrogen atom. The conductive structure of the oxide film is destroyed by the above second heating step under reduced pressure by removing an oxygen atom, a carbon atom and a hydrogen atom from the oxide film once formed so that the volume resistivity of the oxide film is increased to an order to 10¹ to 10⁵ Ωcm. This increase in volume resistivity can be suitably controlled by the degree of depressurization, the heating temperature and the heating time at the time of heating.

The degree of depressurization in the second heating step is preferably 10² Pa or less, more preferably 10⁻² to 10¹ Pa as absolute pressure. The heating time is preferably 0.5 to 1 hour, more preferably 1 to 30 minutes. The heating temperature is preferably the temperature specified above as the heating temperature for forming an oxide film or lower than this according to the types of the metal compounds in use.

An oxygen atom is filled in the destroyed conductive structure by the third heating step in an oxidizing atmosphere which is carried out subsequently, thereby reducing the volume resistivity of the oxide film again. By suitably selecting the heating temperature and the heating time, a volume resistivity which is about 10² to 10³ times the original value can be achieved. It is assumed that, since only an oxygen atom out of the lost oxygen atom, carbon atom and hydrogen atom is filled in the conductive structure destroyed by the second heating step in this third heating step, a film having a different conductive structure from that of the original oxide film is obtained.

The third heating step in the oxidizing atmosphere is preferably carried out in an oxygen-containing gas, for example, air or oxygen. The gas at the time of heating may have any pressure, for example, 5×10⁴ to 1×10⁶ Pa. The heating time is preferably 1 minute to 1 hour, more preferably 3 to 30 minutes. The heating temperature may be the same as the heating temperature for forming an oxide film according to the types of the metal compounds in use.

In the above process for forming an amorphous conductive oxide film according to the present invention, after a coating film is formed by applying the precursor composition of the present invention to the substrate, a patterned mold is placed on the coating film to sandwich the coating film between the substrate and the patterned mold, and then the coating film is heated in an oxidizing atmosphere, thereby making it possible to form a patterned oxide film.

That is, this process for forming a patterned oxide film comprises the steps of:

applying the precursor composition to the substrate to form a coating film;

placing a patterned mold on the coating film to sandwich the coating film between the substrate and the patterned mold; and

heating the coating film in an oxidizing atmosphere.

This process for forming a patterned film is called “nanoimprint lithography”.

The substrate used herein, the method of coating the precursor composition to the substrate and the thickness of the coating film to be formed are the same as those in the above process for forming an amorphous conductive oxide film.

The patterned mold used in this process for forming a patterned oxide film may be made of the same material as what have been described as materials constituting the substrate. Out of these, silicon, quartz, silicon with an oxide film, silicone resin (such as polydimethylsiloxane (PDMS)) and metals (such as nickel) are preferred because they have high workability, can form a fine pattern and are excellent in the releasability of the formed patterned oxide film.

The pattern of the above patterned mold is a line-and-space pattern, columnar or polygonal columnar (such as square pillar-like) pattern, conical or polygonal pyramid-like (such as square pyramid-like) pattern, projection or hole pattern obtained by cutting these with a plane, or pattern which is a combination thereof, or the patterned mold may have a mirror surface.

According to the above process for forming a patterned oxide film, a patterned film to which the arbitrary fine pattern of the patterned mold as a parent pattern has been preferably transferred can be formed, and an oxide film with a pattern having a width of 10 nm or more, preferably 50 nm or more and an aspect ratio of 5 or less, preferably 3 or less can be transferred. The aspect ratio is a value obtained by dividing the height of each line with the width of each line or space in the case of the line-and-space pattern, a value obtained by dividing the height of each projection with the diameter or the length of one side of the projection in the case of a projection pattern, or a value obtained by dividing the depth of each hole with the diameter or the length of one side of the hole in the case of a hole pattern.

The patterned mold is placed on the coating film formed on the substrate as described above and pressed against the coating film as required so that the coating film can be sandwiched between the substrate and the patterned mold. The pressure for pressing the patterned mold is preferably 0.1 to 10 MPa.

To place the patterned mold on the coating film, at least one of the substrate and the patterned mold is preferably subjected to a release treatment. Examples of the releasing agent which can be used herein include surfactants (such as fluorine-based surfactants, silicone-based surfactants and nonionic surfactants) and fluorine-containing diamond-like carbon (F-DLC).

The heating of the coating film may be carried out while the coating film is held in the space between the substrate and the patterned mold or after the patterned mold on the coating film is removed.

The heating temperature, the heating time and the oxidizing atmosphere are the same as those in the above process for forming an amorphous conductive oxide film. Even when heating is carried out while the coating film is held in the space between the substrate and the patterned mold, an oxide film having sufficiently high electrical conductivity can be formed by making the ambient atmosphere an oxidizing atmosphere.

It is easily understandable for a person having ordinary skill in the art that the volume resistivity of the patterned oxide film formed as described above can be adjusted by further carrying out the second heating step under reduced pressure and the third heating step in an oxidizing atmosphere on the patterned oxide film.

The amorphous conductive oxide film or the patterned amorphous conductive oxide film can be formed as described above.

The conductive oxide film (including the patterned conductive oxide film) formed by the process of the present invention has high electrical conductivity. By selecting the types and amounts of suitable metal atoms and the heating temperature, the volume resistivity of the conductive oxide film can be set to 0.5 Ωcm or less, preferably 0.1 Ωcm or less, more preferably 0.05 Ωcm, particularly preferably 0.01 Ωcm or less.

The conductive oxide film formed by the process of the present invention exhibits p-type semiconducting properties. The oxide film formed by the process of the present invention exhibits a positive Seebeck coefficient value which is an index for p-type semiconducting properties at a wide temperature range. When a rhodium compound is used as the metal compound (B), the Seebeck coefficient becomes a large positive value and accordingly, extremely clear p-type semiconducting properties are obtained. The carrier density of the oxide film formed by the process of the present invention is almost in the order of 10¹⁵ to 10²¹ carriers/cm³, specifically about 10¹⁷ carriers/cm³.

Since the amorphous oxide film (including the patterned amorphous oxide film) formed by the process of the present invention tends to be little crystallized even when it is further heated, a fine electrode or wire having few restrictions on the crystal size can be easily formed in the production process of an electronic device. Therefore, the amorphous conductive oxide film formed by the process of the present invention can be advantageously used in various electronic devices, for example, as a material for the gate electrodes of thin-film transistors.

The details of the structure of the oxide film obtained by the process of the present invention are still unknown. However, it is made clear by analysis made by the inventors of the present invention that the oxide film has composition represented by the following general formula (1).

(Ln_{y}A_{1-y})ₐBOₓC_{b}H_{c} (1)

(In the above formula (1), Ln is at least one metal ion selected from among lanthanoids (excluding cerium), A is at least one metal ion selected from among lead, bismuth, nickel, palladium, copper and silver, B is at least one metal ion selected from among ruthenium, iridium, rhodium and cobalt, “a” is a number of 0.3 to 6.0, “y” is a number of 0 or more and less than 1, “x” is a number which is 0.1 to 0.9 times the total valence of Ln, A and B, “b” is a number of 0 to (a+1), and “c” is a number of 0 to {2×(a+1)}.) When the oxide film does not undergo the second heating step under reduced pressure and the third heating step in an oxidizing atmosphere, or when the oxide film undergoes both of the second heating step and the third heating step, the value of the above “x” is 0.25 to 0.9 times the total valence of Ln, A and B. When the oxide film undergoes the second heating step but not the third heating step, the value of the above “x” is 0.1 time or more and less than 0.5 time the total valence of Ln, A and B.

The value of “b” or “c” or the values of both of them in the above general formula (1) can be made extremely small by adjusting the conditions in an oxidizing atmosphere after the formation of the coating film, especially the concentration of an oxidant (such as oxygen) and the heating time. In this case, the concentration of a carbon atom or a hydrogen atom or both in the formed film can be made below the detection limit of RBS/HFS/NRA analysis (Rutherford back scattering spectrum/hydrogen forward scattering spectrum/nuclear reaction analysis). When a bismuth compound is used as the metal compound (A2), this effect becomes marked and the value of “b” or “c” or the values of both of them can be easily made substantially “0”. When a bismuth compound is not used as the metal compound (A2) (that is, A in the above general formula (1) is at least one metal ion selected from among lead, nickel, palladium, copper and silver), the value of “b” in the above general formula (1) is preferably larger than 0 and (a+1) or less, and the value of “c” is preferably larger than 0 and 2×(a+1) or less. In this case, “b” is a number of preferably 0.05 to (a+1), more preferably 0.1 to (a+1), and “c” is a number of preferably 0.05 to 2×(a+1), more preferably 0.1 to 2×(a+1).

The above expression “the total valence of Ln, A and B” means the total of formal valence calculated by multiplying the contents of metal atoms based on the assumption that the ion valence of a metal atom contained in the metal compound in use is as follows.

Lanthanoid: valence of +3
Lead: valence of +2
Bismuth: valence of +3
Nickel: valence of +2
Palladium: valence of +2
Copper: valence of +2
Silver: valence of +1
Ruthenium: valence of +4
Iridium: valence of +4
Rhodium: valence of +3
Cobalt: valence of +3

### EXAMPLES

In the following examples, measurements were made under the following conditions.

### [X-Ray Diffraction Measurement Conditions]

Measurement apparatus: M18XHF-SRA of MacScience Co., Ltd.
Line source: Cu Kα line
Specimen size: 1 cm×2 cm
Voltage and current: 40 kV, 60 mA
Measurement range: 2 θ=10 to 50′
Scanning rate: 5°/min

### [Volume Resistivity]

The volume resistivity was measured by the four probe method.

### <Preparation of Composition for Forming a Conductive Oxide Film>

In the following preparation examples, the following compounds were used as metal sources of oxides. That is, a commercial product of Kanto Chemical Co., Inc. (trihydrate salt, purity of 99.9 wt %, abbreviated as “Pb-ac” in Table 1) was used as lead acetate (II);

a commercial product of Alfa Aesar GmbH & Co. KG (anhydrous salt, purity of 99 wt %, abbreviated as “Bi-ac” in Table 1) was used as bismuth acetate (III);
a commercial product of Wako Pure Chemical Industries, Ltd. (tetrahydrate salt, purity of 99.9 wt %, abbreviated as “Ni-ac” in Table 1) was used as nickel acetate (II);
a commercial product of Alfa Aesar GmbH & Co. KG (anhydrous salt, purity of 99.99 wt %, abbreviated as “Ru-noac” in Table 1) was used as ruthenium nitrosylacetate (III);
a commercial product of ChemPur GmbH (anhydrous salt, Ir content of about 48 wt %, abbreviated as “Ir-ac” in Table 1) was used as iridium acetate (III);
a commercial product of ChemPur GmbH (anhydrous salt, Rh content of 35 to 40 wt %, abbreviated as “Rh-ac” in Table 1) was used as rhodium acetate; and
a commercial product of Kanto Chemical Co., Inc. (1.5 hydrous salt, purity of 99.99 wt %, abbreviated as “La-ac” in Table 1) was used as lanthanum acetate.

### [Preparation of Composition for Forming a Conductive Oxide Film]

### Preparation Examples 1 to 15

Types and amounts shown in Table 1 of metal sources and propionic acid were weighed and put in a glass bottle having an inner capacity of 13.5 mL, and an amount shown in Table 1 of monoethanolamine was added dropwise slowly to the above mixture at room temperature under agitation. The bottle was stoppered tightly and heated on a hot plate set at 150° C. while the content was stirred for a time shown in Table 1 to dissolve the raw materials. An amount shown in Table 1 of 1-butanol was added to the obtained slightly viscous solution so as to dilute it, thereby obtaining a solution having a total metal concentration of 0.135 mole/kg.

TABLE 1
preparation of compositions for forming a conductive oxide film

| | Types and amounts of metal | Metal atom | Propionic | Mono- | Heating | |
|---|---|---|---|---|---|---|
| Ex. | sources | ratio | acid | ethanolamine | time | 1-butanol |
| 1 | Pb-ac 0.166 g, Ru-noac 0.135 g | Pb_{1.0}Ru_{1.0} | 2.199 g | 0.75 g | 40 min | 3.25 g |
| 2 | Bi-ac 0.169 g, Ru-noac 0.135 g | Bi_{1.0}Ru_{1.0} | 2.195 g | 0.75 g | 40 min | 3.25 g |
| 3 | Bi-ac 0.169 g, Ir-ac 0.172 g | Bi_{1.0}Ir_{1.0} | 2.159 g | 0.75 g | 2 h | 3.25 g |
| 4 | Bi-ac 0.169 g, Rh-ac 0.118 g | Bi_{1.0}Rh_{1.0} | 2.213 g | 0.75 g | 2 h | 3.25 g |
| 5 | Ni-ac 0.109 g, Rh-ac 0.118 g | Ni_{1.0}Rh_{1.0} | 2.273 g | 0.75 g | 2 h | 3.25 g |
| 6 | Ni-ac 0.109 g, Rh-ac 0.118 g, | Ni_{1.0}Rh_{1.0}Ir_{1.0} | 3.350 g | 1.125 g | 2 h | 4.875 g |
| | Ir-ac 0.172 | | | | | |
| 7 | Ni-ac 0.109 g, Rh-ac 0.059 g, | Ni_{2.0}Rh_{1.0}Ir_{1.0} | 2.246 g | 0.75 g | 2 h | 3.25 g |
| | Ir-ac 0.086 | | | | | |
| 8 | La-ac 0.075 g, Pb-ac 0.083 g, | La_{0.5}Pb_{0.5}Ru_{1.0} | 2.207 g | 0.75 g | 40 min | 3.25 g |
| | Ru-noac 0.135 g | | | | | |
| 9 | La-ac 0.0375 g, Pb-ac 0.166 g, | La_{0.5}Pb_{2.0}Ru_{1.0} | 1.917 g | 0.66 g | 40 min | 2.84 g |
| | Ru-noac 0.675 g | | | | | |
| 10 | La-ac 0.0375 g, Pb-ac 0.249 g, | La_{0.5}Pb_{3.0}Ru_{1.0} | 2.459 g | 0.84 g | 40 min | 3.66 g |
| | Ru-noac 0.675 g | | | | | |
| 11 | La-ac 0.045 g, Bi-ac 0.118 g, | La_{0.3}Bi_{0.7}Ru_{1.0} | 2.202 g | 0.75 g | 40 min | 3.25 g |
| | Ru-noac 0.135 g | | | | | |
| 12 | La-ac 0.150 g, Bi-ac 0.085 g, | La_{1.0}Bi_{0.5}Ru_{1.0} | 2.756 g | 0.94 g | 40 min | 4.06 g |
| | Ru-noac 0.135 g | | | | | |
| 13 | La-ac 0.150 g, Bi-ac 0.169 g, | La_{1.0}Bi_{1.0}Ru_{1.0} | 3.296 g | 1.13 g | 40 min | 4.88 g |
| | Ru-noac 0.135 g | | | | | |
| 14 | La-ac 0.150 g, Bi-ac 0.254 g, | La_{1.0}Bi_{1.5}Ru_{1.0} | 3.836 g | 1.31 g | 40 min | 5.69 g |
| | Ru-noac 0.135 g | | | | | |
| 15 | La-ac 0.045 g, Bi-ac 0.118 g, | La_{0.3}Bi_{0.7}Ir_{1.0} | 2.165 g | 0.75 g | 2 h | 3.25 g |
| | Ir-ac 0.172 g | | | | | |

Ex.: Preparation Example

### <Formation and Evaluation of Conductive Oxide Film>

### Example 1

In this example, the influences of the metal type and the metal atom ratio upon crystallinity and electrical conductivity of the obtained oxide were investigated.

### (1) General Film Formation Process

The composition for forming a conductive oxide film prepared in each of the above Preparation Examples was spin coated on a 20 mm×20 mm silicon substrate having an oxide film on the surface at a revolution of 2,000 rpm for 25 seconds and heated in air on a hot plate set at 150° C. for 6 seconds, at 250° C. for 1 minute and further at 400° C. for 5 minutes sequentially to obtain an oxide film. This cycle consisting of spin coating and sequential heating was carried out three times in total to obtain an oxide film having a thickness of 60 nm.

The above oxide film was additionally heated at 500° C. for 30 minutes, at 550° C. for 20 minutes, at 600° C. for 10 minutes, at 650° C. for 10 minutes, at 700° C. for 10 minutes, at 750° C. for 10 minutes and at 800° C. for 10 minutes in an oxygen stream having a velocity of 0.2 L (STP)/min.

### (2) General Measuring Methods

The X-ray diffraction and the volume resistivity after heating at 400° C. for forming the oxide film having a thickness of 60 nm and after additional heating at each temperature in the above film formation process were measured by the above methods after heating or additional heating at the temperature specified in each Example which will be described hereinafter.

### (3) Crystallinity of Oxide Film

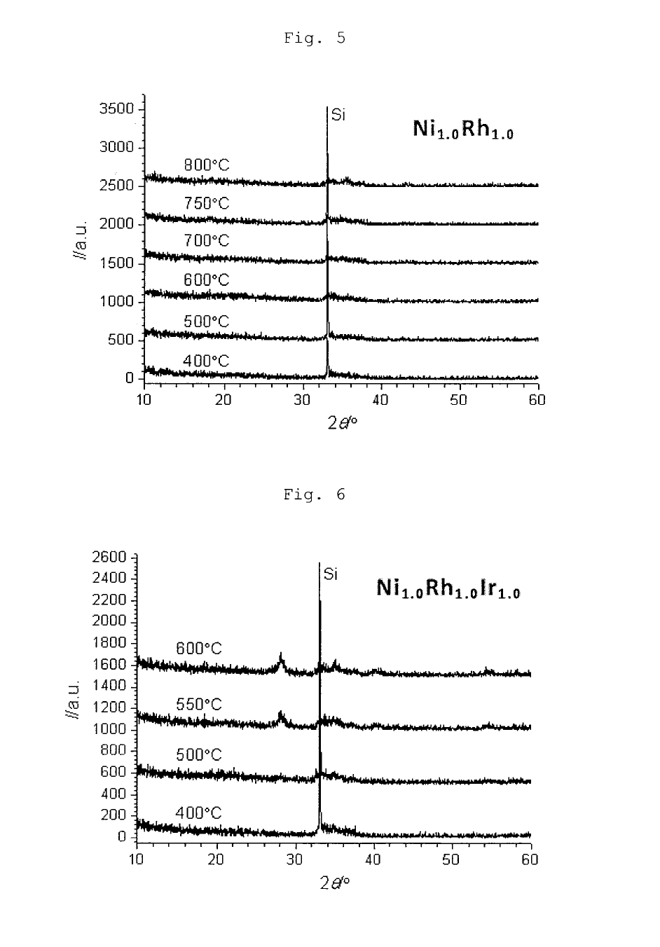

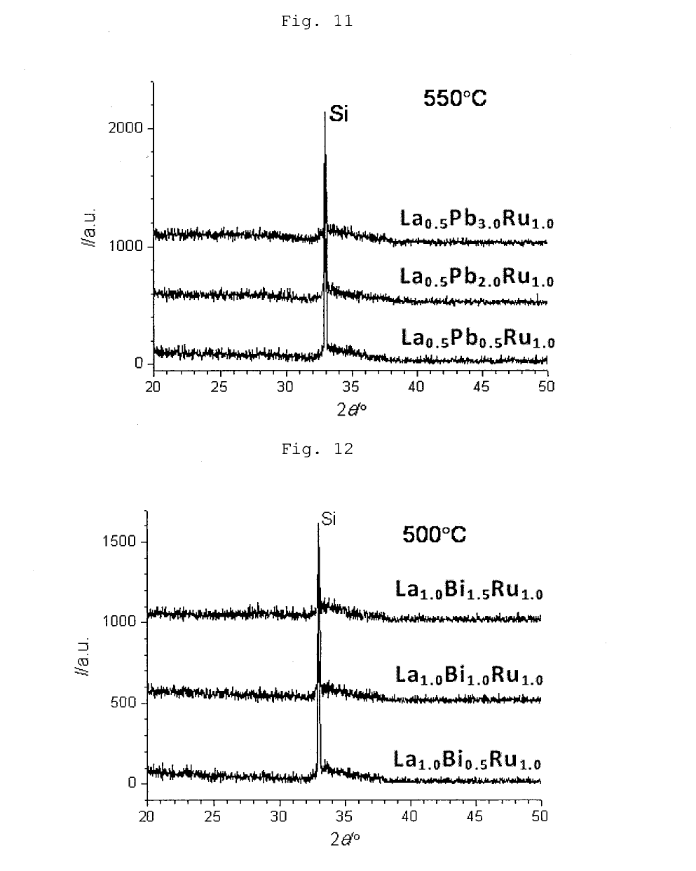

The X-ray diffraction charts of oxide films formed from the compositions for forming a conductive oxide film obtained in the above Preparation Examples are shown in FIGS. 1 to 12.

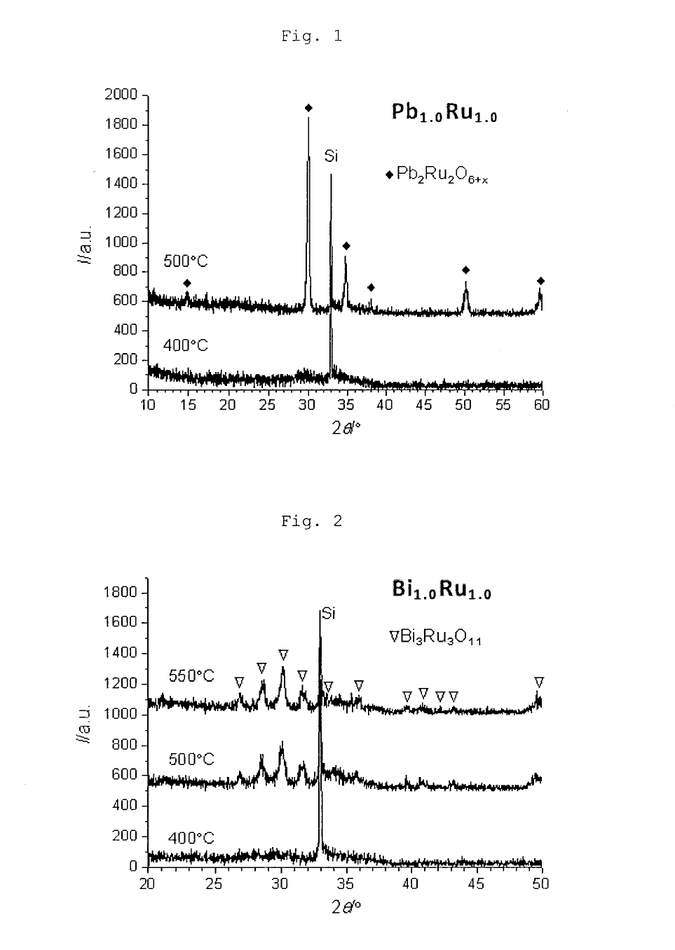

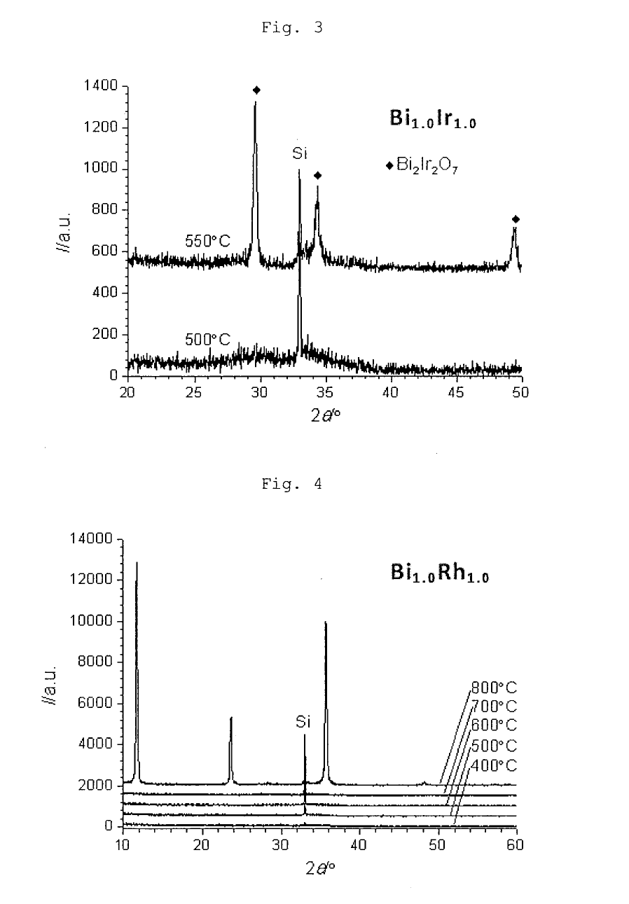

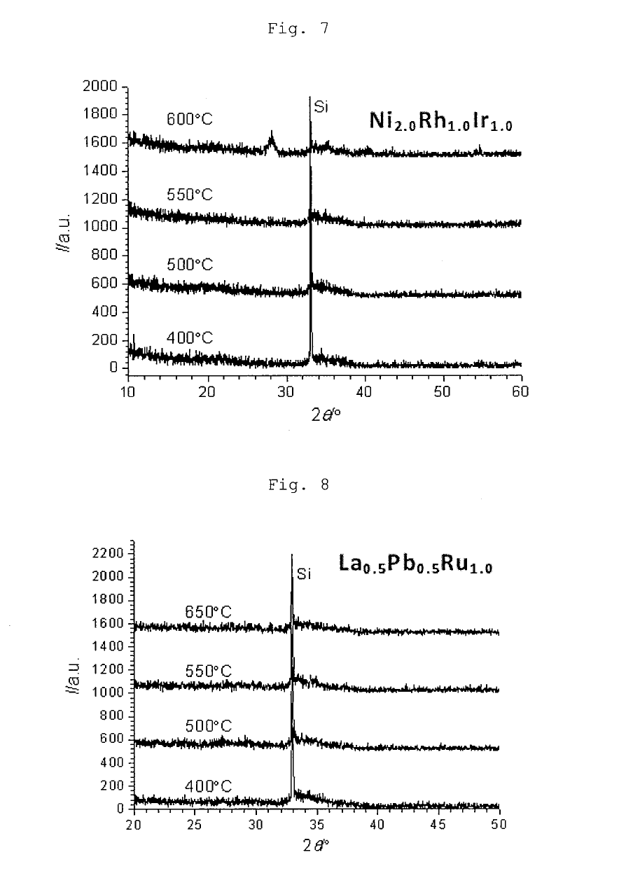

Although oxide films formed from compositions for forming conductive oxide films having metal atom ratios Pb_{1.0}Ru_{1.0} and Bi_{1.0}Ru_{1.0} were amorphous after heating at 400° C., a crystallinity peak was seen after additional heating at 500° C. (FIGS. 1 and 2). In the case of a metal atom ratio Bi_{1.0}Ir_{1.0}, the oxide film was amorphous after additional heating at 500° C., and in the case of Bi_{1.0}Rh_{1.0} and Ni_{1.0}Rh_{1.0}, the oxide films were amorphous after additional heating at 700 to 750° C. (FIGS. 3 to 5). In the case of Ni_{1.0}Rh_{1.0}Ir_{1.0} and Ni_{2.0}Rh_{1.0}Ir_{1.0}, the oxide films kept amorphous at a temperature up to 500 to 550° C. (FIGS. 6 and 7).

When a rhodium compound was used as the component (B), a stable amorphous structure was obtained.

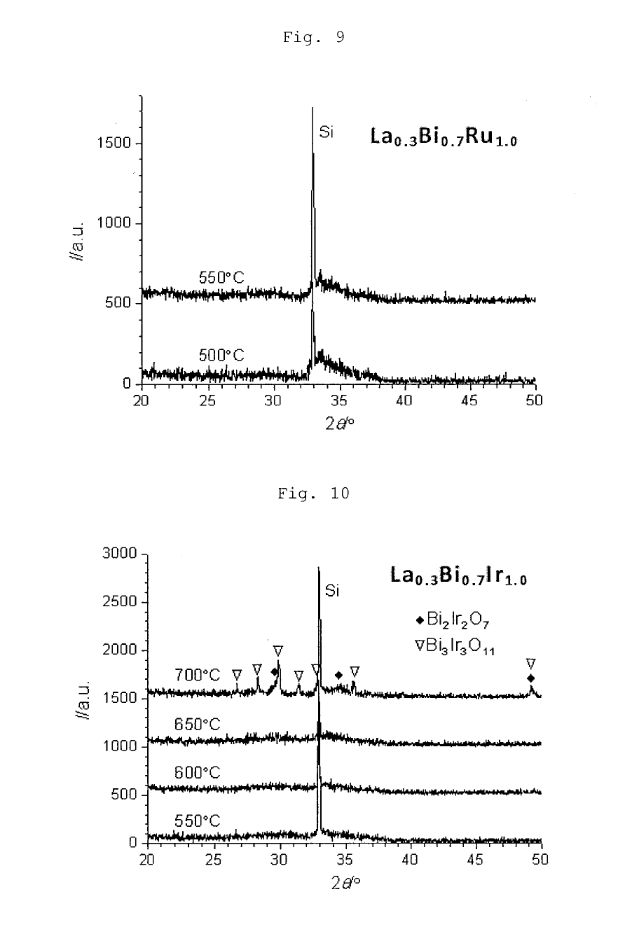

In contrast to this, an oxide film formed from a composition for forming a conductive oxide film, comprising a lanthanum compound as the component (A1), kept an amorphous structure after additional heating at a high temperature regardless of the type of the component (B). That is, in the case of La_{0.5}Pb_{0.5}Ru_{1.0}, La_{0.3}Bi_{0.7}Ru_{1.0} and La_{0.3}Bi_{0.7}Ir_{1.0}, the obtained oxide films were amorphous at a temperature up to 550 to 650° C. (FIGS. 8 to 10).

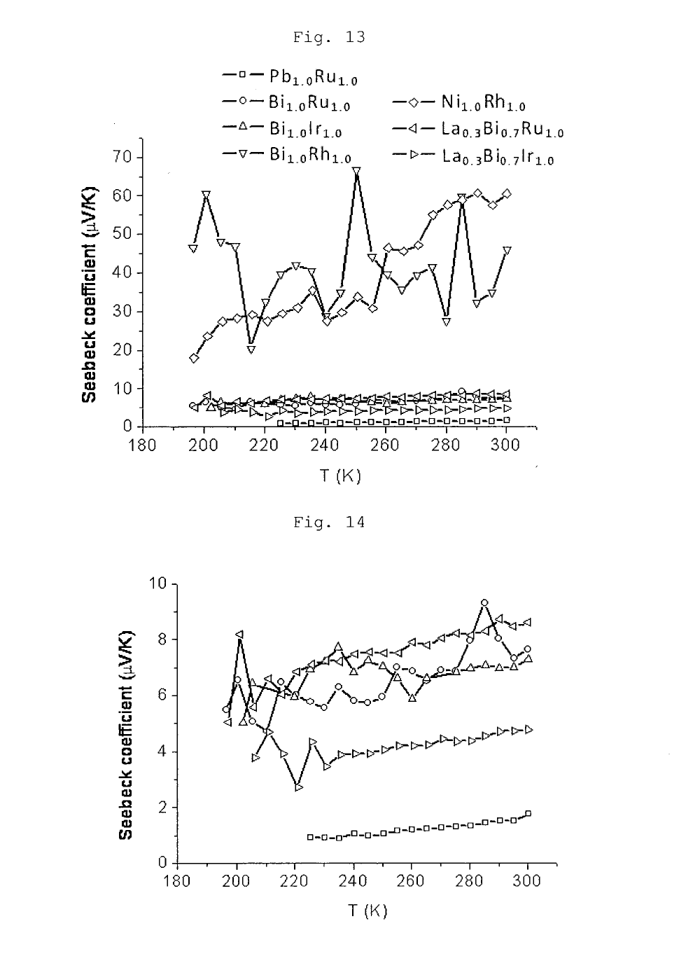

Further, when the X-ray diffractions after additional heating at 550° C. or 500° C. of LaPbRu-based and LaBiRu-based oxide films were investigated by changing the metal atom ratio, the obtained oxide films kept an amorphous structure (FIGS. 11 and 12).

### (4) Volume Resistivity of Oxide Film

Next, the volume resistivity of each of the oxide films formed above after heating or additional heating at each temperature was measured by the four probe method.

The measurement results are shown in Table 2. “--” in Table 2 means that the volume resistivity of an oxide film in the column was unmeasured, and “(crys)” means that a crystal peak was seen in the X-ray diffraction chart of the film by additional heating at the given temperature.

TABLE 2
Volume resistivity of conductive oxide film

| | Volume resistivity (Ωcm) | | | | | |
|---|---|---|---|---|---|---|
| | Heating | | | | | |
| Metal atom | temperature | Additional heating temperature | | | | |
| ratio | 400° C. | 500° C. | 550° C. | 600° C. | 650° C. | 700° C. |
| Pb_{1.0}Ru_{1.0} | 0.0016 | (crys) | — | — | — | — |
| Bi_{1.0}Ru_{1.0} | 0.002 | 0.0048(crys) | — | — | — | — |
| Bi_{1.0}Ir_{1.0} | 0.0029 | 0.002 | 0.0084 (crys) | — | — | — |
| Bi_{1.0}Rh_{1.0} | 0.18 | 0.034 | — | 0.012 | 0.01 | 0.015 |
| Ni_{1.0}Rh_{1.0} | 0.025 | 0.028 | — | 0.035 | — | 0.041 |
| Ni_{1.0}Rh_{1.0}Ir_{1.0} | 0.0053 | 0.0053 | 0.0023 (crys) | — | — | — |
| Ni_{2.0}Rh_{1.0}Ir_{1.0} | 0.0096 | 0.0096 | 0.009 | 0.0028 (crys) | — | — |
| La_{0.5}Pb_{0.5}Ru_{1.0} | 0.0053 | 0.0078 | 0.018 | — | — | — |
| La_{0.5}Pb_{2.0}Ru_{1.0} | 0.13 | — | — | — | — | — |
| La_{0.5}Pb_{3.0}Ru_{1.0} | 0.96 | — | — | — | — | — |
| La_{0.3}Bi_{0.7}Ru_{1.0} | 0.0033 | 0.0048 | 0.0072 | — | — | — |
| La_{1.0}Bi_{0.5}Ru_{1.0} | 0.086 | 0.052 | — | — | — | — |
| La_{1.0}Bi_{1.0}Ru_{1.0} | 0.28 | 0.16 | — | — | — | — |
| La_{1.0}Bi_{1.5}Ru_{1.0} | 0.6 | 0.34 | — | — | — | — |
| La_{0.3}Bi_{0.7}Ir_{1.0} | 0.035 | 0.004 | 0.0034 | 0.0032 | 0.0036 | 0.020 (crys) |

Excluding a case where the Bi:Rh atom ratio was 1.0:1.0 and a case where the component (B) was a ruthenium compound and the ratio of the ruthenium atom to the total of all metal atoms was ⅓ (mole/mole) or less, the obtained oxide films showed a volume resistivity in the order of 10⁻² to 10⁻³ Ωcm by heating at 400° C. or higher. When the above Bi:Rh atom ratio was 1.0:1.0, the obtained oxide film showed a volume resistivity in the order of 10⁻² Ωcm by additional heating at 500° C. or higher.

### Example 2

In this example, the carrier type of the formed conductive oxide film was investigated. The compositions for forming a conductive oxide film prepared in the above Preparation Examples 1 to 5, 11 and 15 were used.

Each of the above compositions was spin coated on a 20 mm×20 mm quartz glass substrate at a revolution of 2,000 rpm for 25 seconds and then heated in air on a hot plate set at 150° C. for 6 seconds, at 250° C. for 1 minute and at a film forming temperature shown in Table 3 for 5 minutes sequentially to obtain an oxide film. The above operation was repeated for each oxide film so that the number of film formation cycles, each consisting of spin coating and sequential heating steps, became the number of cycles shown in Table 3. One film formation cycle in Table 3 means that the film formation cycle consisting of spin coating and sequential heating steps is carried out once and not repeated.

Further, an oxide film for measurement was obtained by carrying out the additional heating of each of the above oxide films in an air stream or oxygen stream having a velocity of 0.2 L(STP)/min under conditions shown in Table 3. The thickness of each of the obtained oxide films is shown in Table 3. The film forming temperature is a temperature at which the amorphous structure of the oxide film is maintained.

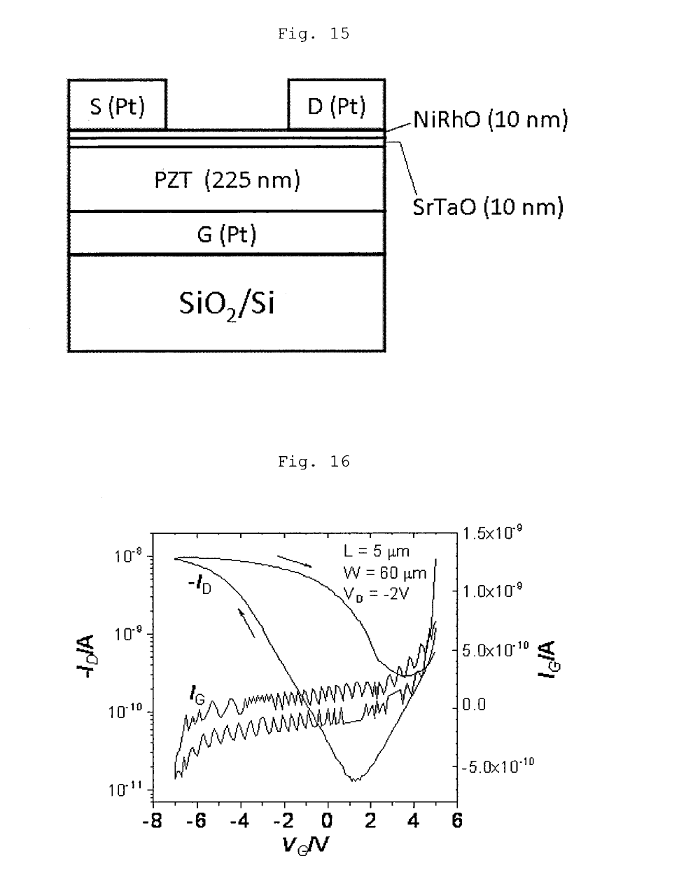

The Seebeck coefficients at each measurement temperature of these oxide films were investigated by using a Hall effect•resistivity measuring instrument (ResiTest8300 of TOYO Corporation). Graphs showing the temperature dependence of the Seebeck coefficient are shown in FIG. 13 and FIG. 14. FIG. 13 shows the curves of all the specimens. FIG. 14 shows an enlarged graph of five specimens having a small value on the vertical axis in FIG. 13. The identification of the curves of FIG. 14 is the same as in FIG. 13.

Since the Seebeck coefficients were positive values at all the measurement temperatures, it was confirmed that all the oxide films measured in this example had p-type semiconducting properties at the measurement temperature range. It is noted that the Seebeck coefficient was especially large when a rhodium compound was used as the component (B).

TABLE 3
Formation of oxide films for Seebeck formation measurement

| | | Number of | | |
|---|---|---|---|---|
| Metal | Film | film | Additional | Film |
| atom | forming | formation | heating | thickness |
| ratio | temperature | cycles | conditions | (nm) |
| Pb_{1.0}Ru_{1.0} | 350° C. | 1 | 350° C., | 20 |
| | | | 30 min, | |
| | | | in air | |
| Bi_{1.0}Ru_{1.0} | 400° C. | 1 | 400° C., | 20 |
| | | | 30 min, | |
| | | | in air | |
| Bi_{1.0}Ir_{1.0} | 400° C. | 3 | 500° C., | 60 |
| | | | 30 min, | |
| | | | in oxygen | |
| Bi_{1.0}Rh_{1.0} | 400° C. | 1 | 600° C., | 20 |
| | | | 10 min, | |
| | | | in oxygen | |
| Ni_{1.0}Rh_{1.0} | 400° C. | 3 | 550° C., | 60 |
| | | | 20 min, | |
| | | | in air | |
| La_{0.3}Bi_{0.7}Ru_{1.0} | 400° C. | 2 | 500° C., | 40 |
| | | | 30 min, | |
| | | | in oxygen | |
| La_{0.3}Bi_{0.7}Ir_{1.0} | 400° C. | 2 | 500° C., | 40 |
| | | | 30 min, | |
| | | | in oxygen | |

### Example 3

In this example, the relationship between the additional heating temperature especially in a low-temperature range and the volume resistivity of each of the formed conductive oxide films was investigated. The compositions for forming a conductive oxide film prepared in the above Preparation Examples 2, 5 and 11 were used.

Each of the above compositions was spin coated on a 20 mm×20 mm silicon substrate having an oxide film on the surface at a revolution of 2,000 rpm for 25 seconds and then heated in air on a hot plate set at 150° C. for 10 seconds and additionally heated on a hot plate under conditions shown in Table 4. All the oxide films had a thickness of about 20 nm.

The volume resistivity of each of the oxide films after the heating step was measured by the four probe method. The measurement results are shown in Table 4.

When the metal atom ratio was Bi_{1.0}Ru_{1.0} and La_{0.3}Bi_{0.7}rRh_{1.0}, the obtained oxide films exhibited electrical conductivity after additional heating at 250° C., and in the case of Ni_{1.0}Rh_{1.0}, the obtained oxide film exhibited electrical conductivity after additional heating at 270° C. It was confirmed that the above oxide films achieved electrical conductivity by heating at a low temperature. These oxide films have extremely high electrical conductivity and can be advantageously used in electrodes. Meanwhile, in the case of Ni_{1.0}Rh_{1.0}, the formed oxide film exhibited preferable electrical conductivity as a semiconductor.

TABLE 4

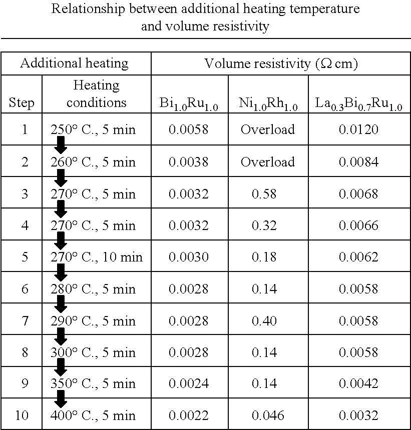

### Example 4

In this example, changes in volume resistivity were investigated when the second heating step under reduced pressure and the third heating step in an oxidizing atmosphere were carried out after the formation of an oxide film. The compositions for forming a conductive oxide film prepared in the above Preparation Examples 5 and 15 were used.

### Example 4-1

### Metal Atom Ratio Ni_{1.0}Rh_{1.0}, Composition of Preparation Example 5

The composition for forming a conductive oxide film having a metal atom ratio Ni_{1.0}Rh_{1.0} prepared in the above Preparation Example 5 was spin coated on a 20 mm×20 mm quartz glass substrate at a revolution of 2,000 rpm for 25 seconds and then heated in air on a hot plate set at 150° C. for 6 seconds, at 250° C. for 1 minute and at 400° C. for 5 minutes sequentially. The operation of spin coating and sequential heating was repeated three times on the same substrate to obtain an oxide film.

The oxide film obtained above was additionally heated at 550° C. for 20 minutes in an air stream having a velocity of 0.2 L (STP)/min. The oxide film after this additional heating had a film thickness of 60 nm and a volume resistivity measured by the four probe method of 0.021 Ωcm.

Then, the oxide film after the above additional heating was heated at 550° C. for 20 minutes under vacuum (0.7 Pa). Attempts were made to measure the volume resistivity by the four probe method of this oxide film after heating under vacuum but the resistance value exceeded the measurement limit.

Further, the oxide film after heating under vacuum was additionally heated (reoxidized) again in an air stream having a velocity of 0.2 L (STP)/L at 450° C. for 10 minutes. The volume resistivity measured by the four probe method of this oxide film after additional heating was 25 Ωcm.

When the semiconducting properties of the above oxide film after reoxidization were investigated, it had a hall coefficient of +34 cm³/C, a carrier density of +1.8×10¹⁷ cm³ and a hall mobility of 1.4 cm²/Vs. Since the hall coefficient and the carrier density were positive values, it was confirmed that this oxide film had p-type semiconducting properties. It is considered from the above carrier density and hall mobility that this oxide film can be advantageously used in the channel of a transistor.

### Example 4-2

### Metal Atom Ratio La_{0.3}Bi_{0.7}Ir_{1.0}, Composition of Preparation Example 15

The composition for forming a conductive oxide film having a metal atom ratio La_{0.3}Bi_{0.7}Ir_{1.0} prepared in the above Preparation Example 15 was spin coated on a 20 mm×20 mm quartz glass substrate at a revolution of 2,000 rpm for 25 seconds and then heated in air on a hot plate set at 150° C. for 6 seconds, at 250° C. for 1 minute and at 400° C. for 5 minutes sequentially to obtain an oxide film. This oxide film was additionally heated at 500° C. for 30 minutes in an oxygen stream having a velocity of 0.2 L(STP)/min. The oxide film after this additional heating had a film thickness of 20 nm and a volume resistivity measured by the four probe method of 0.0048 Ωcm.

Then, the oxide film after the above additional heating was heated at 650° C. for 5 minutes under vacuum (0.5 Pa). The volume resistivity measured by the four probe method of the oxide film after heating under vacuum was 2.4 Ωcm. Although attempts were made to measure the volume resistivity of an oxide film after heating under vacuum under the same conditions as above by the four probe method, it was overloaded.

Thereafter, the oxide film after heating under vacuum was additionally heated (reoxidized) again at 650° C. for 5 minutes in an oxygen stream having a velocity of 0.2 L(STP)/min. The volume resistivity measured by the four probe method of this oxide film after reoxidization was 0.45 Ωcm.

It was confirmed that the volume resistivity of the oxide film formed by the process of the present invention was increased by heating under vacuum and reduced by reoxidization. The electrical conductivity of the oxide film can be easily controlled to a desired level by making use of this property.

### Example 5

In this example, it was verified whether the oxide film formed by the process of the present invention could be used in the channel of a transistor. The composition for forming a conductive oxide film having a metal atom ratio Ni_{1.0}Rh_{1.0} prepared in the above Preparation Example 5 was used.

### (1) Production of Thin-Film Transistor

A commercial product (manufactured by Tanaka Kikinzoku Kogyo K.K.) which is a laminate consisting of a silicon substrate having an oxide film on the surface and a platinum layer as a gate electrode formed on the oxide film was used as a substrate.

(1-1) Formation of PZT layer

A PZT solution (8 wt % solution, Pb:Zr:Ti=120:40:60 (atom ratio), manufactured by Mitsubishi Materials Corporation) was spin coated on the platinum surface of the above substrate at a revolution of 2,500 rpm for 25 seconds and then heated in air on a hot plate set at 250° C. for 5 minutes to form a film. After this film formation cycle consisting of spin coating and heating steps was repeated 5 times in total, the film was additionally heated at 400° C. for 10 minutes and at 600° C. for 20 minutes in air to form a PZT layer on the platinum surface (film thickness of 225 nm).

(1-2) Formation of SrTaO layer

1.568 g of bis(2-methoxyethoxy) strontium (18 to 20 wt % product in methoxyethanol, manufactured by Alfa Aesar GmbH & Co. KG), 0.547 g of butoxytantalum (purity of 98 wt %, manufactured by Aldrich) and 7.89 g of methoxyethanol were fed to a glass bottle having a capacity of 13.5 mL, and the bottle was stoppered tightly and placed on a hot plate set at 100° C. for 1 hour to dissolve these materials under agitation. Methoxymethanol was added to the obtained solution so as to dilute it to 3 times in weight ratio. The obtained dilution was used as a solution for forming a film.

This solution was spin coated on the PZT surface formed above at a revolution of 1,500 rpm for 25 seconds and then heated in air on a hot plate set at 150° C. for 10 seconds and at 250° C. for 10 minutes sequentially to form a film. Further, the film was additionally heated at 350° C. for 20 minutes in air to form a SrTaO layer on the PZT surface (film thickness of 10 nm).

(1-3) Formation of channel layer (NiRhO layer)

1-butanol was added to the composition for forming a conductive oxide film having a metal atom ratio Ni_{1.0}Rh_{1.0} prepared in the above Preparation Example 5 to dilute it to 2 times in weight ratio. This dilution was used as a solution for forming a film.

This solution was spin coated on the SrTaO surface formed above at a revolution of 2,000 rpm for 25 seconds and then heated in air on a hot plate set at 150° C. for 10 seconds and at 250° C. for 10 minutes sequentially to form a channel layer (NiRhO layer) on the SrTaO surface (film thickness of 10 nm).

### (1-4) Formation of Source Electrode and Drain Electrode

Platinum was sputtered on the channel layer formed above at room temperature, and a lift-off process was carried out for patterning so as to form a source electrode and a drain electrode.

### (1-5) Cell Separation

Finally, the channel layer (NiRhO layer) between adjacent transistors was removed by a dry etching method using a patterned resist film to obtain a thin-film transistor.

The schematic sectional view of the structure of this thin-film transistor is shown in FIG. 15.

### (2) Evaluation of Thin-Film Transistor

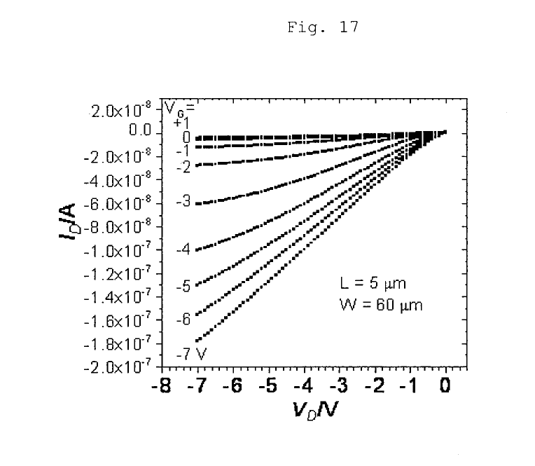

The current transfer characteristics of the thin-film transistor produced above are shown in FIG. 16, and the output characteristics of the thin-film transistor are shown in FIG. 17.

It was confirmed from these figures that the thin-film transistor is turned ON when the gate electrode is at a negative potential and OFF when the gate electrode is at a positive potential. Therefore, it was understood that the channel layer (oxide layer having a metal atom ratio Ni_{1.0}Rh_{1.0}) formed in this example functioned as a p-type semiconductor. The ON/OFF ratio is about 10² which is the maximum value of a p-type oxide semiconductor.

Conventionally, there have been few examples in which an oxide semiconductor exhibiting p-type semiconducting properties actually works as a transistor, and all of the oxide semiconductors have been formed by using a complicated vacuum apparatus. Therefore, this example is the world's first example in which a p-type oxide semiconductor formed by the solution process actually works as a transistor. In addition, the heating temperature employed in this example is so low that it can be applied to plastic substrates.

### Example 6

In this example, elemental analysis was made on an oxide film formed by the process of the present invention. The compositions for forming a conductive oxide film prepared in the above Preparation Examples 1, 2-4, 5 and 11 were used to investigate the film composition by changing film forming conditions.

Each of the above compositions was spin coated on a 20 mm×20 mm silicon substrate having an oxide film on the surface at a revolution of 2,000 rpm for 25 seconds and then heated in air on a hot plate under the conditions described in the column for “hot plate heating” in Table 5 to form an oxide film. Further, the above operation was repeated on each oxide film so that the number of film formation cycles, each consisting of spin coating and sequential heating steps became the number of cycles shown in Table 5. Thereafter, the additional heating of each oxide film was carried out on a hot plate in air or an oxygen stream having a velocity of 0.2 L(STP)/min (in oxygen) or under vacuum (0.7 Pa) under the conditions shown in the column for “additional heating” of Table 5. When the conditions for “hot plate heating” and “additional heating” are connected by an arrow, this means that heating under different conditions was carried out stepwise. The expression “6-10 sec” in the column for “hot plate heating” means that the time of heating which is carried out several times by repeating the film formation cycle is controlled to a range of 6 to 10 seconds.

RBS/HFS/NRA analysis (Rutherford back scattering spectrum/hydrogen forward scattering spectrum/nuclear reaction analysis) was made on the oxide films formed by the above procedure by using the Pelletron 35DH of National Electrostatics Corporation. The analytical results are shown in Table 6 together with theoretical values. The numerical value within the parentheses in the column for film composition indicates the range of a measurement error (error of the least significant figure of a numerical value outside the parentheses. For example, “1.13(5)” means “1.13±0.05”). For the BiIrO-50 specimen, a bismuth atom and an iridium atom could not be separated from each other due to analytical restrictions.

As understood from Table 6, the oxide film formed by the process of the present invention contains at least metal atoms and an oxygen atom and additionally significant amounts of a carbon atom and a hydrogen atom in many cases. Even when a carbon atom and a hydrogen atom are not detected in the obtained oxide film, since at least some of the precursor compounds used as raw materials have an organic group, it is assumed that a carbon atom, a hydrogen atom or both of them are involved in the formation of the oxide film. It is considered that the specific properties of the oxide film formed by the process of the present invention are developed because this exerts an influence upon the structure of the oxide film and the electrical properties of a metal. It is conceivable that the structural contribution of these elements is, for example, the formation of a special metastable structure and the electrical contribution of these elements is the change of the property of a metal atom band.

TABLE 5
Conditions for forming an oxide film for elemental analysis

| | | | Number of | | |
|---|---|---|---|---|---|
| | | | film | | Film |
| Sample | Metal atom | | formation | Additional | thickness |
| name | ratio | Hot plate heating | cycles | heating | (nm) |
| PbRuO-35 | Pb_{1.0}Ru_{1.0} | 150° C., 6-10 sec | 10 | 350° C., 30 min, | 200 |
| | | → 250° C., 1 min | | in air | |
| | | → 350° C., 5 min | | | |
| BiRuO-26 | Bi_{1.0}Ru_{1.0} | 150° C., 6-10 sec | 10 | 260° C., 30 min, | 240 |
| | | → 260° C., 5 min | | in air | |
| BiRuO-40 | Bi_{1.0}Ru_{1.0} | 150° C., 6-10 sec | 10 | 400° C., 30 min, | 200 |
| | | → 250° C., 5 min | | in air | |
| BiIrO-50 | Bi_{1.0}Ir_{1.0} | 150° C., 6-10 sec | 10 | 500° C., 30 min, | 200 |
| | | → 250° C., 1 min | | in oxygen | |
| | | → 400° C., 5 min | | | |
| BiRhO-60 | Bi_{1.0}Rh_{1.0} | 150° C., 6-10 sec | 8 | 600° C., 10 min, | 160 |
| | | → 250° C., 5 min | | in oxygen | |
| NiRhO-25 | Ni_{1.0}Rh_{1.0} | 150° C., 6-10 sec | 5 | 250° C., 30 min, | 130 |
| | | → 250° C., 5 min | | in air | |
| NiRhO-55 | Ni_{1.0}Rh_{1.0} | 150° C., 6-10 sec | 10 | 550° C., 30 min, | 200 |
| | | → 250° C., 1 min | | in oxygen | |
| | | → 400° C., 5 min | | | |
| NiRhO-55vac | Ni_{1.0}Rh_{1.0} | 150° C., 6-10 sec | 10 | 550° C., 30 min, | 200 |
| | | → 250° C., 1 min | | in oxygen | |
| | | → 400° C., 5 min | | → 550° C., 20 min, | |
| | | | | Under vacuum | |
| LBRO-50 | La_{0.3}Bi_{0.7}Ru_{1.0} | 150° C., 6-10 sec | 10 | 500° C., 30 min, | 200 |
| | | → 250° C., 5 min | | in oxygen | |

TABLE 6
Film composition of oxide film

| Name of | | Theoretical |
|---|---|---|
| specimen | Film composition of oxide film | value |
| PbRuO-35 | Pb_{1.0}Ru_{1.10(5)}O_{4.0(3)}H_{0.11(2)}C_{0.15(5)}Cl_{0.08(1)} | Pb_{1.0}Ru_{1.0}O_{3.0} |
| BiRuO-26 | Bi_{1.0}Ru_{1.13(5)}O_{4.6(3)}H_{0.20(5)}Cl_{0.10(2)} | Bi_{1.0}Ru_{1.0}O_{3.5} |
| BiRuO-40 | Bi_{1.0}Ru_{1.11(5)}O_{4.7(3)}Cl_{0.10(2)} | Bi_{1.0}Ru_{1.0}O_{3.5} |
| BiIrO-50 | (BiIr)_{2.0}O_{4.0(3)}C_{0.26(5)} | Bi_{1.0}Ir_{1.0}O_{3.5} |
| BiRhO-60 | Bi_{1.0}Rh_{0.94(1)}O_{3.5(3)}Cl_{0.14(5)} | Bi_{1.0}Rh_{1.0}O_{3.0} |
| NiRhO-25 | Ni_{1.0}Rh_{0.98(6)}O_{4.0(4)}H_{2.1(1)}C_{0.25(7)}Cl_{0.011(4)} | Ni_{1.0}Rh_{1.0}O_{2.5} |
| NiRhO-55 | Ni_{1.0}Rh_{0.97(6)}O_{2.7(3)}H_{2.1(1)}C_{0.80(8)}Cl_{0.013(3)} | Ni_{1.0}Rh_{1.0}O_{2.5} |
| NiRhO-55vac | Ni_{1.0}Rh_{0.95(5)}O_{1.0(1)}H_{0.33(3)}C_{0.15(3)} | Ni_{1.0}Rh_{1.0}O_{2.5} |
| LBRO-50 | La_{0.27(4)}Bi_{0.73(4)}Ru_{1.14(7)}O_{4.5(4)}H_{0.11(3)}C_{0.17(6)}Cl_{0.08(1)} | La_{0.3}Bi_{0.7}Ru_{1.0}O_{3.5} |

### Effect of the Invention

Since the oxide film formed by the process of the present invention is a conductive oxide film which has an amorphous structure and exhibits p-type semiconducting properties, it can be advantageously used as a compound semiconductor in the semiconductor device industry. According to the preferred process of the present invention, since the volume resistivity of the formed conductive oxide film can be controlled to a wide range, a semiconductor film having desired electrical conductivity can be obtained. Further, the process of the present invention is a liquid-phase process, does not require a bulky and expensive apparatus, can reduce the contamination of the apparatus as much as possible, and has low process cost, thereby making it possible to contribute to the curtailment of the production cost of a semiconductor device.

1. A process for producing an amorphous conductive oxide film, the process comprising:
applying a composition to a substrate, thereby forming a coating film, and
first heating the coating film in an oxidizing atmosphere,
wherein the composition comprises:
(A1) a×y parts by mole of at least one first metal compound selected from the group consisting of a metal carboxylate salt, a metal alkoxide, a metal diketonate, a metal nitrate salt, and a metal halide, wherein a metal of the at least one first metal compound is a lanthanoid excluding cerium,
(A2) a×(1−y) parts by mole of at least one second metal compound selected from the group consisting of a metal carboxylate salt, a metal alkoxide, a metal diketonate, a metal nitrate salt, and a metal halide, wherein a metal of the at least one second metal compound is lead, bismuth, nickel, palladium, copper, or silver;
(B) 1 part by mole of at least one third metal compound selected from the group consisting of a metal carboxylate salt, a metal alkoxide, a metal diketonate, a metal nitrate salt, a metal halide, a metal nitrosylcarboxylate salt, a metal nitrosylnitrate salt, a metal nitrosylsulfate salt and a metal nitrosylhalide, wherein a metal of the at least one third metal compound is ruthenium, iridium, rhodium, or cobalt; and
(C) a solvent comprising at least one selected from the group consisting of a carboxylic acid, an alcohol, a ketone, a diol and a glycol ether, and
wherein at least one of the at least one first, second, and third metal compounds is selected from the group consisting of the metal carboxylate salt, the metal alkoxide, the metal diketonate, and the metal nitrosylcarboxylate salt;
a is a number of 0.3 to 6.0; and
y is a number of 0 or more and less than 1.

2. The process according to claim 1, further comprising:
second heating under reduced pressure, and
third heating in an oxidizing atmosphere after the first heating.

3. An amorphous conductive oxide film formed by the process of claim 1.

4. The amorphous conductive oxide film according to claim 3,
wherein the amorphous conductive oxide film is of formula:
(Ln_{y}A_{1-y})ₐBOₓC_{b}H_{c}
where Ln is at least one lanthanide ion, excluding a cerium ion;
A is at least one metal ion selected from the group consisting of lead, bismuth, nickel, palladium, copper and silver;
B is at least one metal ion selected from the group consisting of ruthenium, iridium, rhodium and cobalt;
a is a number of 0.3 to 6.0;
y is a number of 0 or more and less than 1;
x is a number which is 0.1 to 0.9 times a total valence of Ln, A and B;
b is a number of 0 to (a+1); and
c is a number of 0 to {2×(a+1)}.

5. The amorphous conductive oxide film according to claim 3, wherein the amorphous conductive oxide film has at least one p-type semiconducting property.

6. The amorphous conductive oxide film according to claim 4, wherein the amorphous conductive oxide film has at least one p-type semiconducting property.

7. A composition for forming an amorphous conductive oxide film, the composition comprising:
(A1) a×y parts by mole of at least one first metal compound selected from the group consisting of a metal carboxylate salt, a metal alkoxide, a metal diketonate, a metal nitrate salt, and a metal halide, wherein a metal of the at least one first metal compound is a lanthanoid excluding cerium;
(A2) a×(1−y) parts by mole of at least one second metal compound selected from the group consisting of a metal carboxylate salt, a metal alkoxide, a metal diketonate, a metal nitrate salt, and a metal halide, wherein a metal of the at least one second metal compound is lead, bismuth, nickel, palladium, copper, or silver;
(B) 1 part by mole of at least one third metal compound selected from the group consisting of a metal carboxylate salt, a metal alkoxide, a metal diketonate, a metal nitrate salt, a metal halide, a metal nitrosylcarboxylate salt, a metal nitrosylnitrate salt, a metal nitrosylsulfate salt and a metal nitrosylhalide, wherein a metal of the at least one third metal compound is ruthenium, iridium, rhodium, or cobalt; and
(C) a solvent comprising at least one selected from the group consisting of a carboxylic acid, an alcohol, a ketone, a diol and a glycol ether, and
wherein at least one of the at least one first, second, and third metal compounds is selected from the group consisting of the metal carboxylate salt, the metal alkoxide, the metal diketonate, and the metal nitrosylcarboxylate salt;
a is a number of 0.3 to 6.0; and
y is a number of 0 or more and less than 1.

8. An amorphous conductive oxide of formula:
(Ln_{y}A_{1-y})ₐBOₓC_{b}H_{c},
where Ln is at least one lanthanide ion, excluding a cerium ion;
A is at least one metal ion selected from the group consisting of lead, bismuth, nickel, palladium, copper and silver;
B is at least one metal ion selected from the group consisting of ruthenium, iridium, rhodium and cobalt;
a is a number of 0.3 to 6.0;
y is a number of 0 or more and less than 1;
x is a number which is 0.1 to 0.9 times a total valence of Ln, A and B;
b is a number of more than 0 and (a+1) or less; and
c is a number of more than 0 and {2×(a+1)} or less.

9. The amorphous conductive oxide according to claim 8, wherein the amorphous conductive oxide has at least one p-type semiconducting property.

10. The amorphous conductive oxide according to claim 8, wherein the amorphous conductive oxide is a film formed on a substrate.
